(19) United States
(12) Patent Application Publication
(10) Pub. No.: US 2004/0075167 A1
(43) Pub. Date: Apr. 22, 2004

(54) Thermoeletrical component and method for production thereof

(76) Inventors: Joachim Nurnus, Neuenburg (DE); Armin Lambrecht, March (DE)

Correspondence Address: BROOKS KUSHMAN P.C., 1000 TOWN CENTER, TWENTY-SECOND FLOOR, SOUTHFIELD, MI, 48075, US

(21) Appl. No.: 10/380,554

(22) PCT Filed: Aug. 27, 2001
(86) PCT No.: PCT/EP01/09861

(30) Foreign Application Priority Data
Sep. 14, 2000 (DE) 100454194

(51) Int. Cl. H01L 21/48; H01L 35/28

(52) U.S. Cl. 257/712; 257/930; 257/714; 438/122

(57) ABSTRACT

The invention relates to devices for providing a thermoelectric element which is, depending on the design, in particular suited for small powers and relatively high voltages and has the features of performance of conventional thermal generators, and which can be at the same time manufactured at low costs, and it is suggested to connect at least two electrically coupled semiconductor components or one semiconductor component and one metal film on at least one insulating substrate, the substrate being a flexible foil element, a process for the manufacture of such a thermoelectric element is also suggested.

The invention relates to a thermoelectric element and a process for the manufacture thereof. Moreover, the invention relates to a process and device for separating and transferring layer materials for manufacturing such a thermoelectric element.

Thermoelectric elements are increasingly employed in the course of progressing miniaturization. For example, a thermoelectric element in the form of a thermal generator is incorporated into a wristwatch made by Citizen Watch Co., Ltd as a source of current.

The greatest advantage of thermoelectric elements is the lack of mechanically moved parts and, as a result, the high reliability and freedom from maintenance. As these elements are principally thermal engines, their effectiveness is limited by the Camot efficiency. Thus, in a room temperature environment, e.g. with a thermal generator one can achieve an efficiency of maximally 2% (10%) from a temperature difference of 6° K (30 K).

Furthermore, the materials used in the generators limit this efficiency. One can describe this contribution with the so-called thermoelectric figure of merit Z of the materials used (the higher the figure of merit=the higher the efficiency). The fact that the usefulness of the employed materials depends on the figure of merit is similar with all thermoelectric elements.

In room temperature environments, binary, tertiary and sometimes also quaternary V-VI-semiconductor materials are often used today for thermoelectric applications. Standard materials are (Bi₁₋ₓSbₓ)₂(Te_{1-y}Se_{y})₃ compounds because of their high figure of merit.

As these materials have highly anisotropic mechanical and electrical properties due to their crystal structure, the figure of merit Z also highly depends on the crystal orientation used. The figure of merit in the C-plane of the V-VI semiconductor is, for example, higher by the factor two than that in the perpendicular direction. Due to these great differences, monocrystalline or at least highly textured V-VI materials are used for the manufacture of thermoelectric elements. The materials are incorporated e.g. into thermoelectric generators, such that the temperature gradient is applied to the generator along the direction having the better material properties (C-plane).

From DE 69 00 274 U, for example, a thermal generator is known, wherein thermocouple legs made of various materials are alternately vapour-deposited in a meander-like fashion onto an insulating carrier film. Thereby, however, only an operation with a restricted efficiency is possible.

Besides that, from WO 98/44 562, a thermoelectric device as well as a process for the manufacture thereof are known, wherein heterogeneous p- and n-dated semiconductor-segments are arranged on large surfaces of carrier plates and are interconnected to form a thermal generator. However, the manufacture and arrangement of the individual segments is complicated and cannot be universally employed.

Another thermal generator is shown in WO 00/48 255. It has a tubular design and individual thermocouples are arranged on a ceramic base material. The employment of this thermal generator, too, is restricted and complicated to manufacture.

With thermal generators, the taken power is proportional to the area and inversely proportional to the length of the thermolegs. Therefore, the assembly of a generator for high performances is no problem, as the desired voltages and power can be varied by connecting thermocouples in series and in parallel.

However, if one needs small powers at a high voltage, a reduction of the power also requires a reduction of the voltage. That means, in this case, one needs thermocouples having an almost needle-shaped geometry: The length of the thermocouples has to be very long as compared with the cross-sectional area. Due to the mechanical anisotropies of the materials, the realization of these geometries at the same time maintaining the monocrystalline material quality is complicated as the delicate nature of the known thermoelectric semiconductor materials largely restricts the manufacture of such thermocouples with small-diameter sections.

For example, element widths of 0.06 cm in case of bismuth-tellurite and lead-tellurite are already lying at the limits of today's production scope.

It is true that it is known from DE 12 12 607 to manufacture thermocouple legs from semiconductor crystals obtained by splitting them off, however, there are no hints whatsoever as to the practical performance of such a process.

As the desired properties of V-VI materials, which serve as starting materials for thermoelectric elements, are predetermined by the crystal structure of the materials, in most cases common crystal growing processes are employed for manufacturing these materials. The thus grown materials are then cut into pieces, so that the resulting element parts comprise the properties desired for the respective application in the direction required for the respective application.

In conventional deposition methods, due to their crystal structure, V-VI materials normally grow with the Van der Waals planes, along which these materials comprise the better properties, in parallel to the normally monocrystalline support. In case of lateral structures, the materials are subsequently treated by structuring them.

However, as already described, it is extremely problematic to make thermoelectric elements that are suitable for high voltages with a small power. Moreover, such thermoelectric elements are extremely fragile.

It is therefore an object of the invention to provide a thermoelectric element that, depending on the design, is particularly suited for small powers and relatively high voltages, apart from having the features of performance of conventional thermal generators, and the manufacture of which is inexpensive.

According to the invention, this object is achieved by a thermoelectric element having the features of claim 1. Preferred embodiments of the invention are explained in subclaims 2 to 15.

Here, the thermoelectric element according to the invention has the advantage that it can be designed or employed, respectively, as thermoelectric generator, as Peltier cooler and as detector.

It is moreover an object of the invention to provide an inexpensive process for manufacturing a thermoelectric element that, depending on the design, is particularly suited for small powers and relatively high voltages, apart from having the features of performance of conventional thermal generators.

According to the invention, this object is achieved by a process having the features of claim 28.

Further preferred embodiments of this process are explained in subclaims 29 to 35.

The process according to the invention for the manufacture of thermoelectric elements enables the preparation for V-VI materials and permits almost any ratio of area to length of the thermoelectric elements, at the same time maintaining the monocrystalline material properties. Thereby, even almost “needle-shaped” geometries or those geometries with corresponding effects can be realized.

Furthermore, the manufacturing costs can be considerably reduced.

By the combination of inexpensive, well-known and simple crystal growing methods with gluing techniques according to the invention, structures can be realized which can otherwise only be realized by thin-film or thick-film deposition processes with a subsequent structuring. Here, the thermoelectric elements are made of rod shaped bodies (TE-rods) by dividing them across their longitudinal axis. The TE-rods are cut out of crystalline blocks. Moreover, the individual TE-rods used can be already manufactured such that the Van der Waals planes are lying across the longitudinal axis of the rods and have the lateral dimensions required in the future application.

Moreover, the thermoelectric elements manufactured according to the process of the invention have an improved material quality.

If, for example, a small film thickness is needed, with the lift-off process according to the invention, one can transfer the high material quality of the monocrystalline starting materials to the thin films. With conventional thin-film depositions of these materials, this is only possible with a few special substrates which are often unusable for the application.

It is furthermore essential that the process according to the invention can produce new, smaller, cheaper and more efficient thermoelectric elements from highly efficient monocrystalline materials.

Such materials that are possible for the manufacture of more efficient thermoelectric elements are part of a group of materials which are below referred to as layer materials. These are materials, in particular crystal materials, which comprise individual parallel planes of films containing strong bonds, the individual planes of films being coupled to adjacent planes of films via weak bonds. In this case, the strong bonds can be, for example, bonds in the form of a metallic atom lattice structure, and the weak bonds can be caused, for example, by Van der Waals forces. The term layer materials, however, is by no means restricted to metallic materials or semiconductors. Neither are the terms weak resp. strong bonds restricted to bonds between individual atoms.

The layer materials also include those materials which have a film-like design, wherein the bonds in the individual planes of films is effected, for example, on a molecular basis or between relatively large units. For characterizing layer materials it is only essential that there are differently strong bonds in a cross-sectional plane of the material compared to-a direction not lying in this plane.

The special design of such layer materials makes it possible to utilize the differently strong bonds of the elementary elements (or larger components of the material) in order to thus achieve an atomically even or virtually atomically even separation of individual layer planes in parallel to the direction of the strong bonds. In the following, the term layer material is also used for a prefabricated body for subsequent treatment with several parallel cutting planes of a layer material.

A further object underlying the invention is to provide a process and a device for separating and transferring layer materials, in particular crystalline layer materials, for the manufacture of thermoelectric elements in order to render their manufacture cheaper than before.

According to the invention, this object is achieved by a process having the features of claim 16.

Preferred embodiments are represented in subclaims 17 to 27. Moreover, this object is achieved by a device having the features of claim 36.

Advantageous embodiments are explained in subclaims 37 to 41.

The process according to the invention for separating and transferring layer materials enables the employment of these layer materials where hitherto attempts have been made with complicated process optimizations in order to achieve the same material quality by means of film deposition processes.

The described process can be employed for the manufacture of thermoelectric elements even for other layer materials, in particular also for those materials comprising Van der Waals bonds (examples: lubricants, such as MOS₂, WSe₂, insulating film materials, such as mica).

Furthermore, at least one of the possible semiconductor components can also be made of metal, in particular thermocouples of polysilicon/aluminium are possible.

In another design, the process according to the invention also permits the transfer from one stack to the next one. In this design, by an appropriate deposition of the separated piece of material onto a second support (also crystal rod), even new combinations (p/n/p/n-film stack) can be realized.

Therefore, the process and the device for separating and transferring layer materials directly or in an adapted form can also be employed for the thick- and thin-film processes, where a film component or a semiconductor or metal element are deposited onto special bases. Here, the transfer process can be used for taking up the element or the component from the base and it can intermediately store or transfer the elements taken up.

In the following, the invention is described in detail with reference to preferred embodiments and process sections and with reference to the drawings. In the drawings:

FIG. 1a shows a perspective view of a grown monocrystal;

FIG. 1b shows a perspective view of a cuboid rod cut out of a monocrystal;

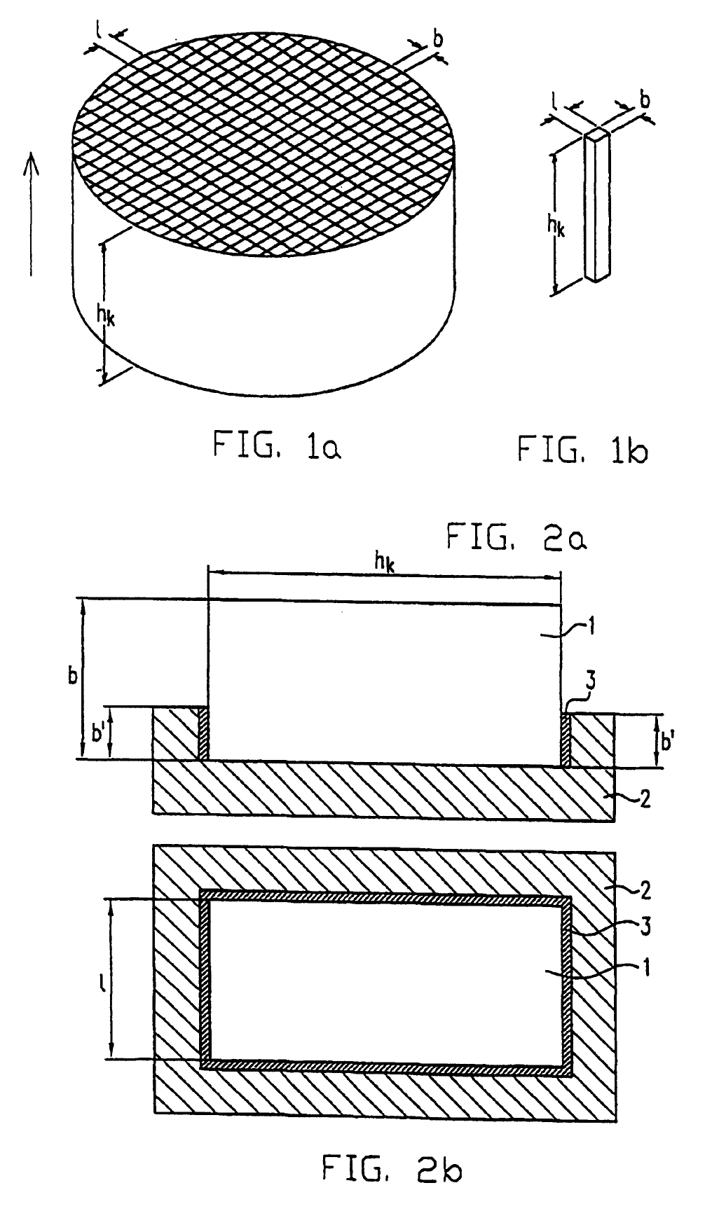

FIG. 2a shows a cross-sectional view of a rod represented in FIG. 1b which is glued into a mounting;

FIG. 2b shows a plan view onto the rod glued into the mounting;

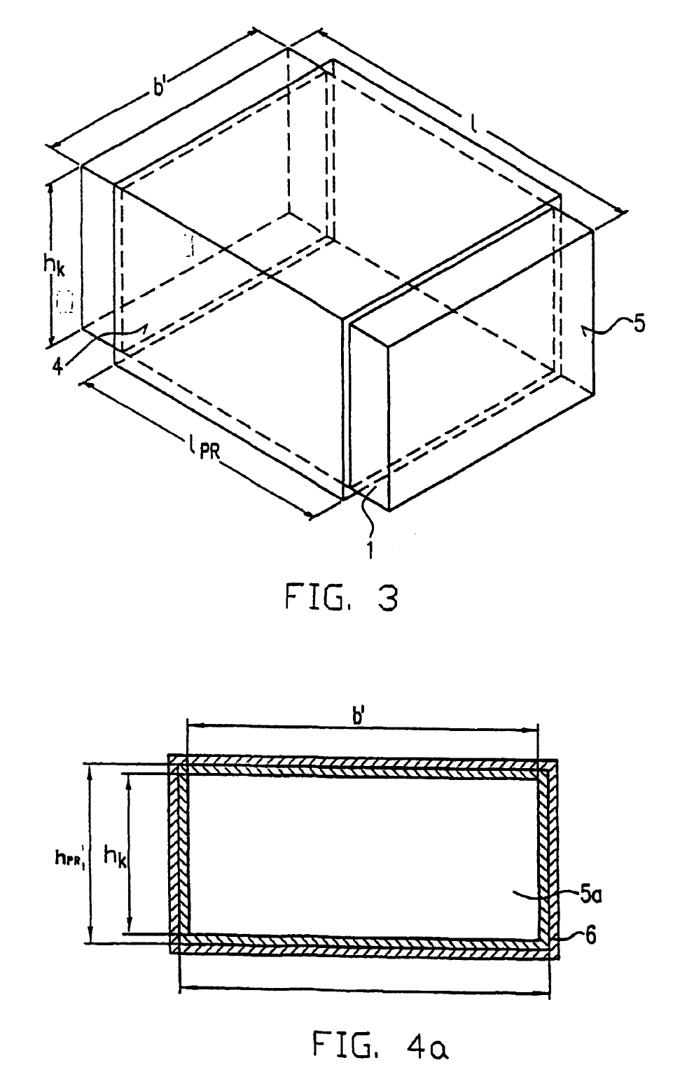

FIG. 3 shows a perspective view of a thinned or planarised rod which is coated with a first film of a shading (photosensitive resist) at parts of its side faces;

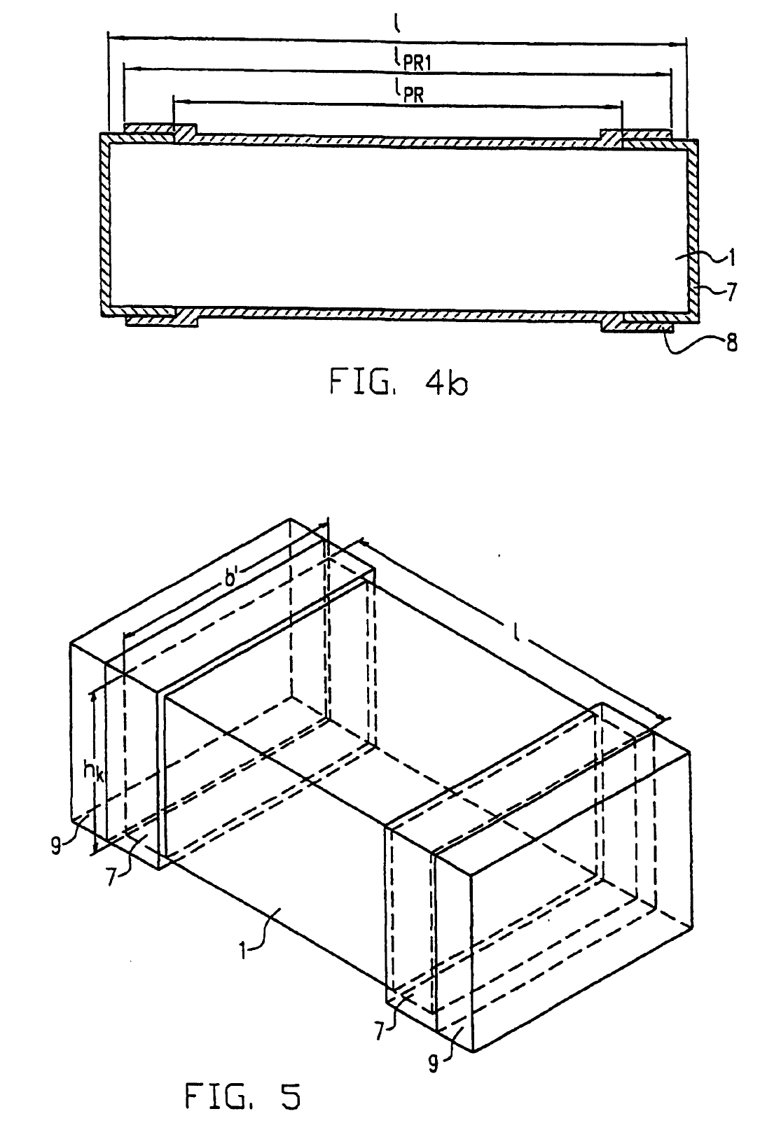

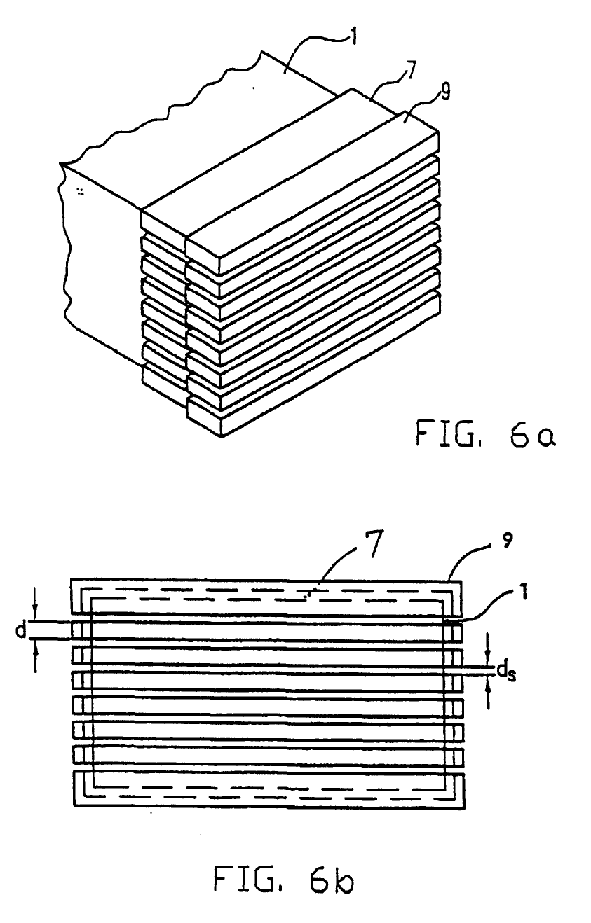

FIG. 4a shows a cross-sectional view through the rod with an applied diffusion barrier film and a second shading;

FIG. 4b shows a longitudinal section through the rod with an applied diffusion barrier film where the second film of the shadings is applied in a modified form (not across the whole length of the rod);

FIG. 5 shows a perspective view of the rod after the removal of the shadings and after the application of the contact material onto the diffusion barrier at the front sides of the rod;

FIG. 6a shows a side view of the rod with applied diffusion barrier and contact material where the break-off areas are designed by sawing corresponding to a first process;

FIG. 6b shows a view of a front side of the rod represented in FIG. 6a;

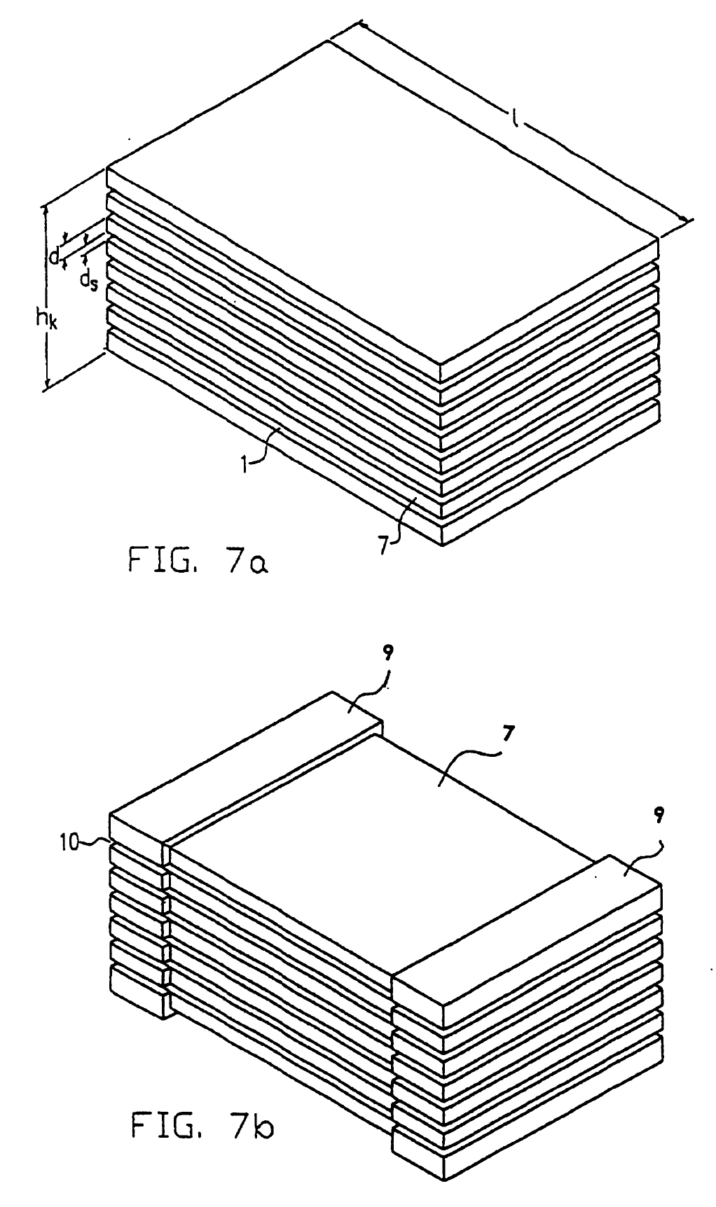

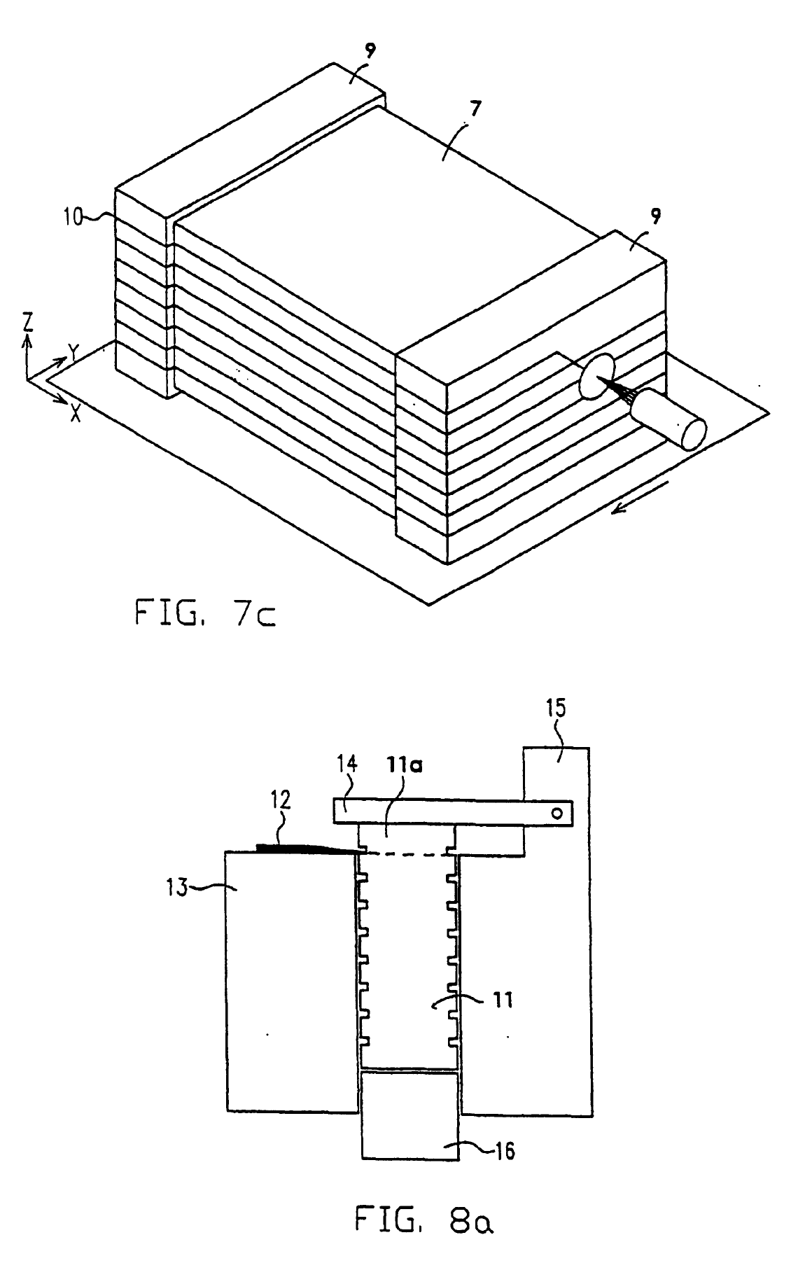

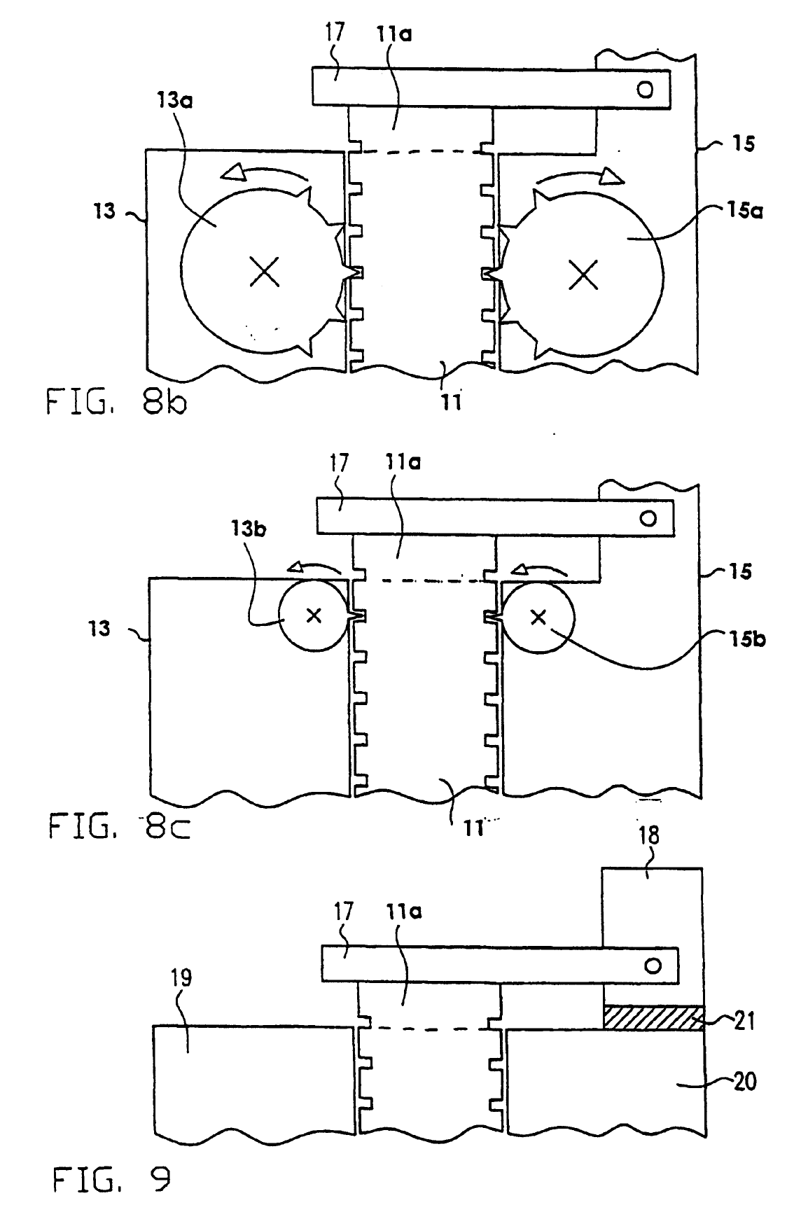

FIG. 7a shows a representation of an alternative process for forming break-off areas by means of laser cutting;

FIGS. 7b,c show a representation of another process for forming break-off areas by means of photolithography and a subsequent etching procedure;

FIGS. 8a, b, c show a principal representation of the removal of films along the break-off areas corresponding to a first process by means of splitting with a blade;

FIG. 9 shows a principal representation of the removal of films along the break-off area according to another process by means of thermal stresses;

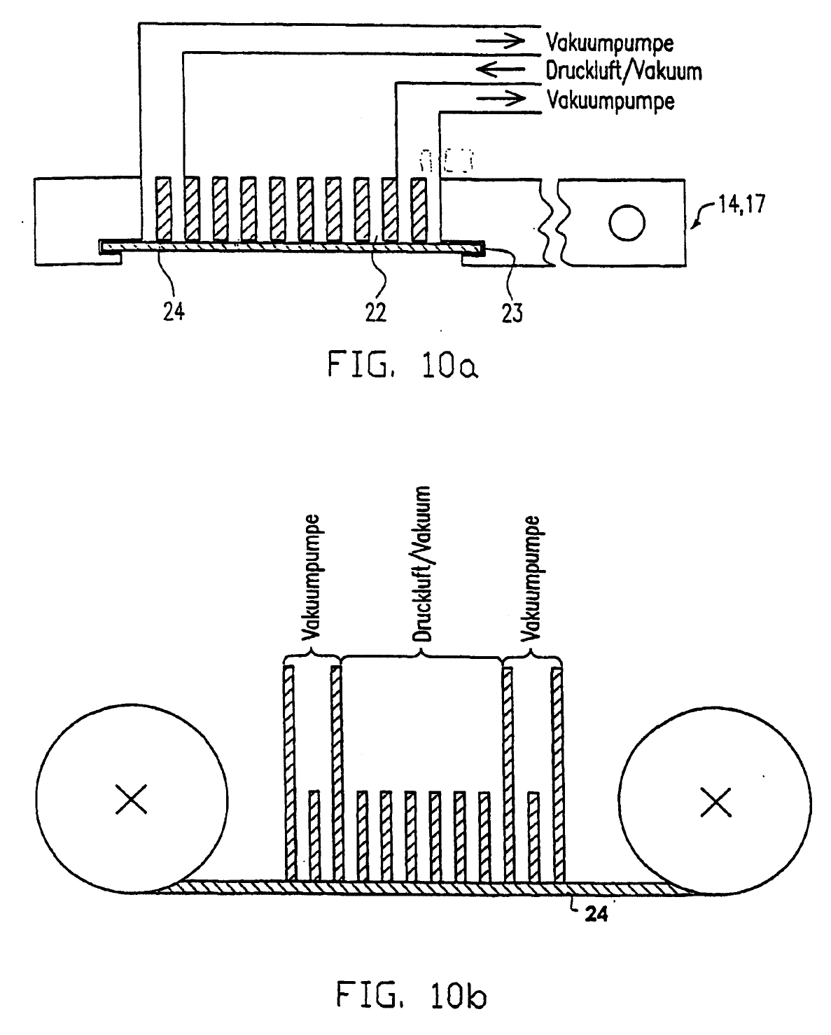

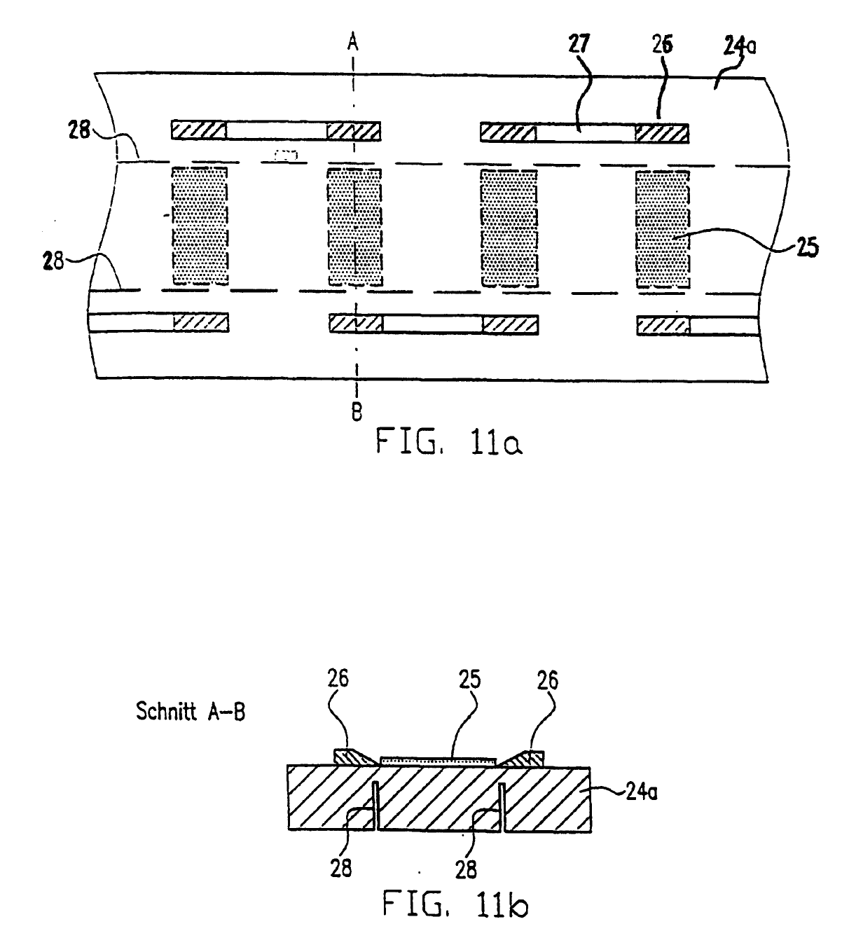

FIGS. 10a, b show a principal representation through the mounting shown in FIGS. 8, 9 for adhesive strips of substrate in cross- and longitudinal section;

FIG. 11a shows a plan view onto a strip of substrate corresponding to a first embodiment where contact elements are applied on the surface;

FIG. 11b shows a cross-sectional view along a line A-B of the strip of substrate represented in FIG. 11a;

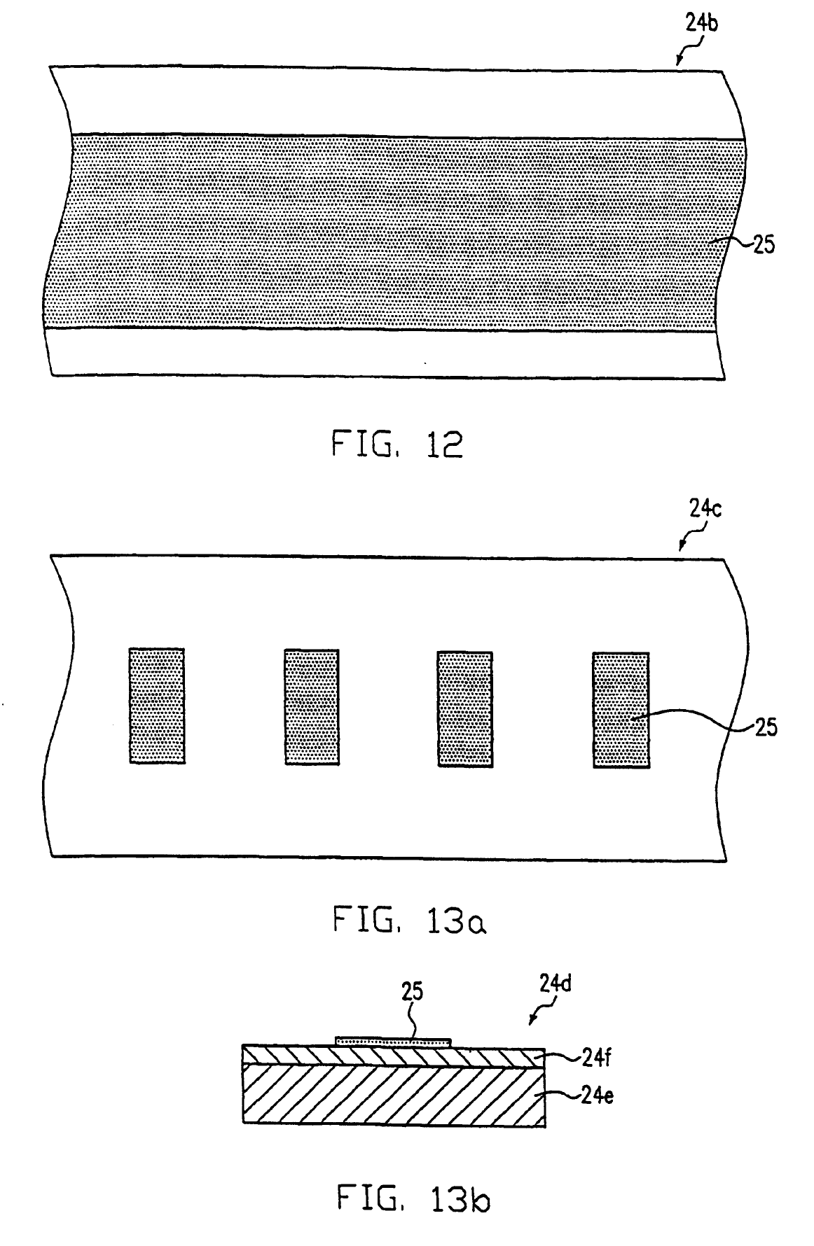

FIG. 12 shows a plan view onto a strip of substrate according to a second embodiment;

FIG. 13a shows plan view onto a strip of substrate according to a third embodiment;

FIG. 13b shows a cross-section of a strip of substrate according to a fourth embodiment with a plurality of films;

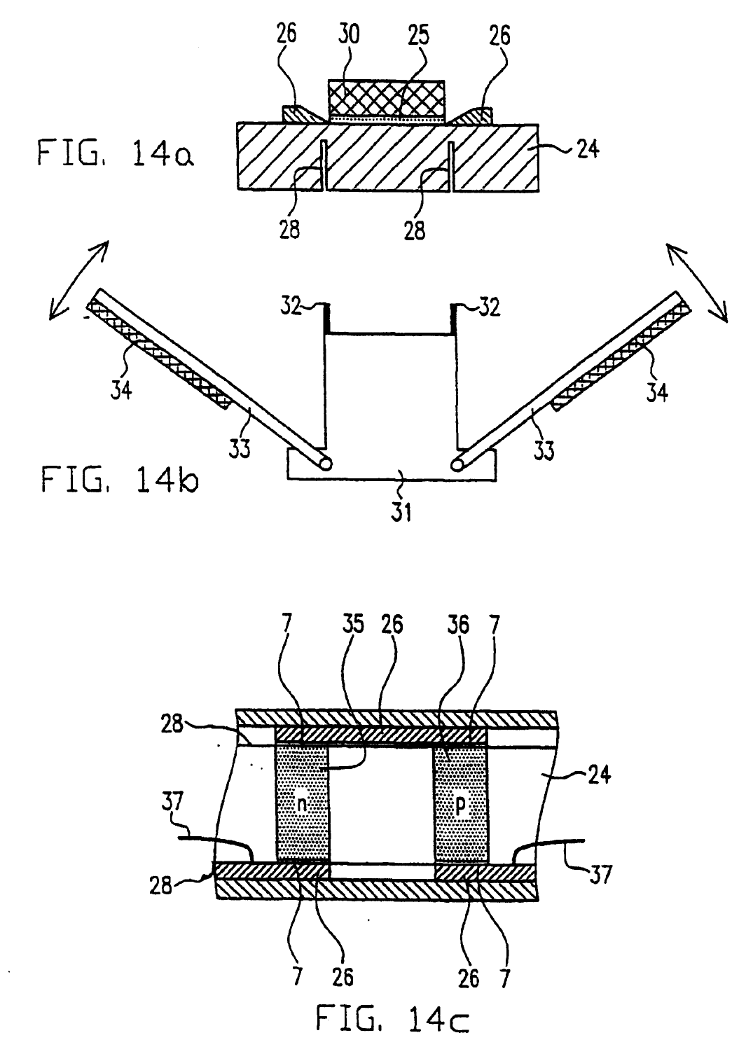

FIG. 14a shows a section through a strip of substrate of the first embodiment according to FIG. 11b on which a film element of the rod is fixed;

FIG. 14b shows a principal representation of a device by means of which this strip of substrate is bent twice along its longitudinal axis;

FIG. 14c shows a plan view onto the strip of substrate represented in FIG. 14a in an already bent form, where the contact elements of the strip of substrate are connected with the bonded film elements;

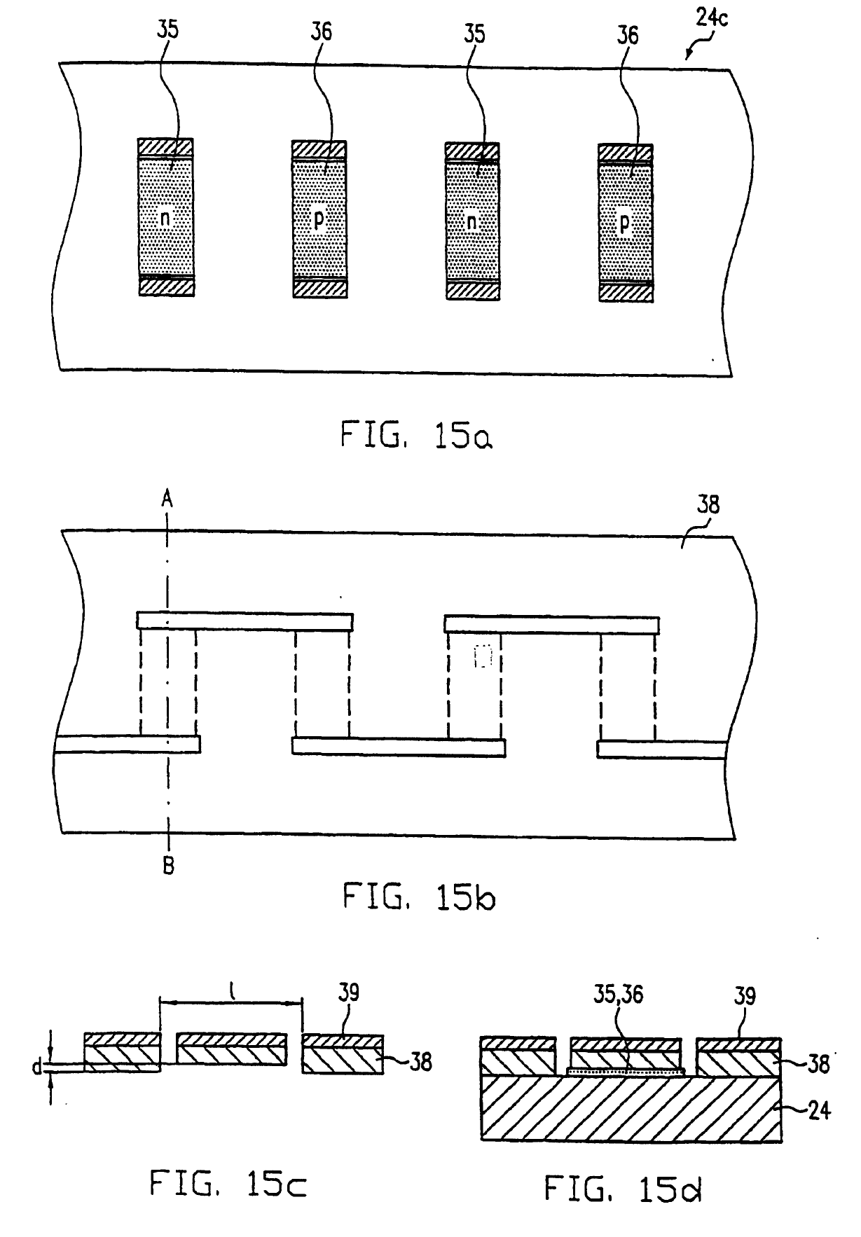

FIG. 15a shows a plan view onto a fitted foil of substrate of the third embodiment;

FIG. 15b shows a plan view onto a double sided bonding sheet with release layer and recesses;

FIG. 15c shows a cross-sectional view along the line A-B through the foil represented in FIG. 15b;

FIG. 15d shows a cross-sectional view of the foils represented in FIGS. 15a, 15b and 15c, which are already fitted, before the contact connections between the film elements are applied;

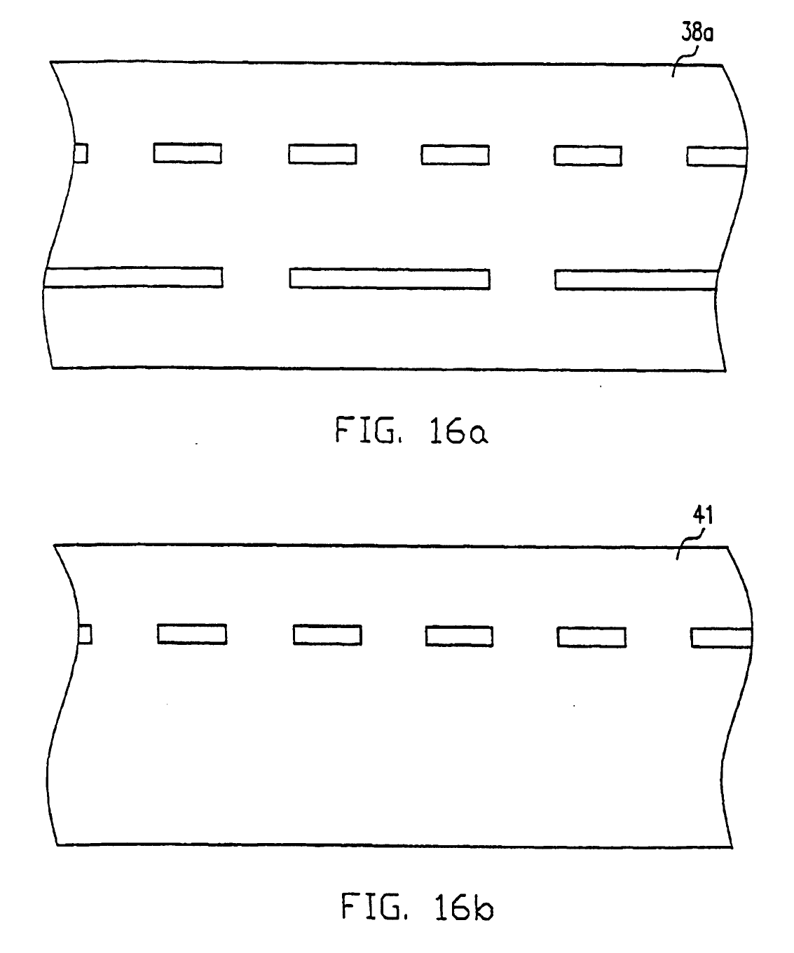

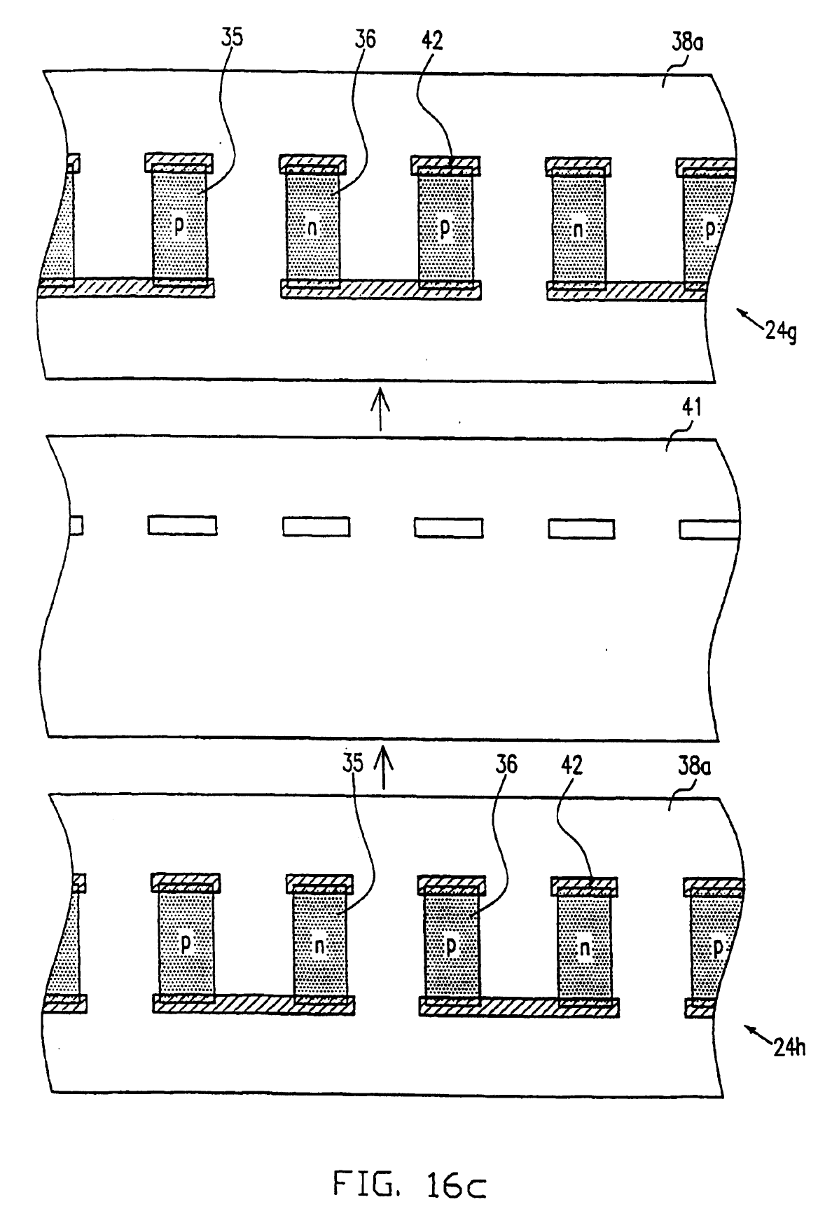

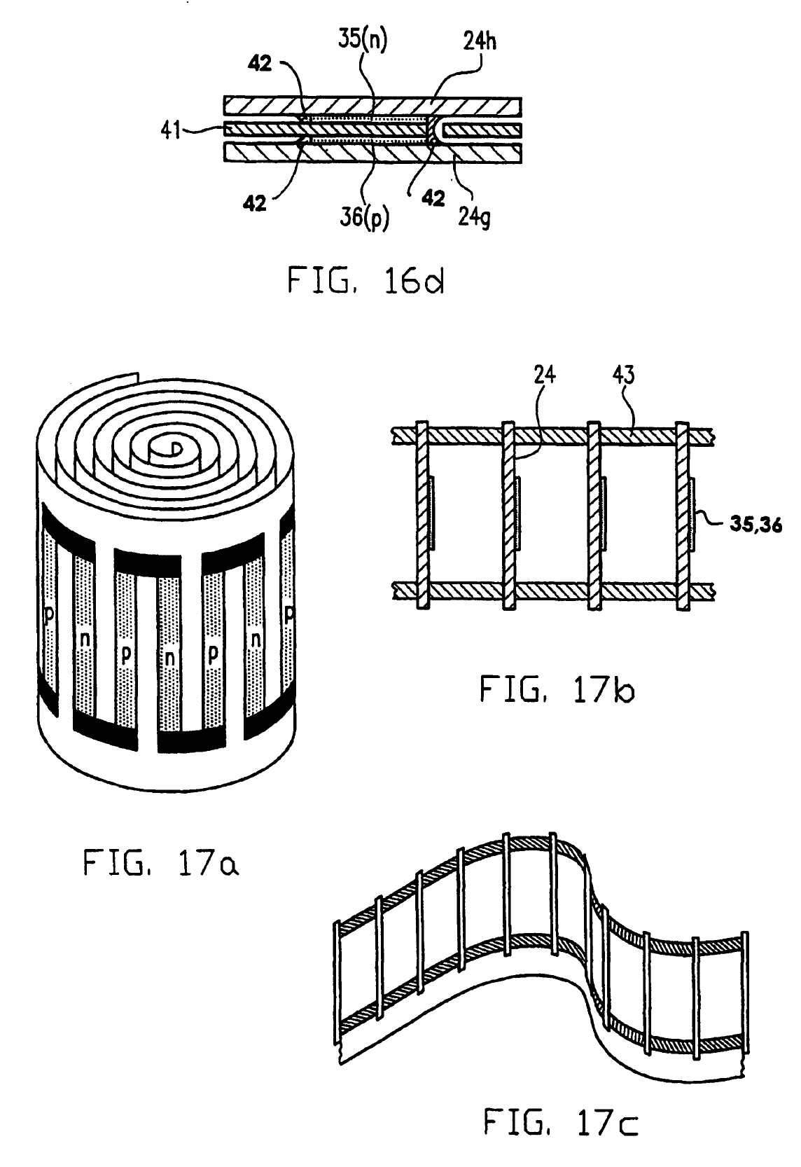

FIG. 16a shows a plan view onto a shadow mask with recesses;

FIG. 16b shows a plan view onto a double sided bonding sheet with differently arranged recesses;

FIG. 16c shows a systematic representation of the joining of two foils of substrate with electrical contacts and film elements;

FIG. 16d shows a cross-sectional view of a TE-element joined and provided with contacts according to FIG. 16c;

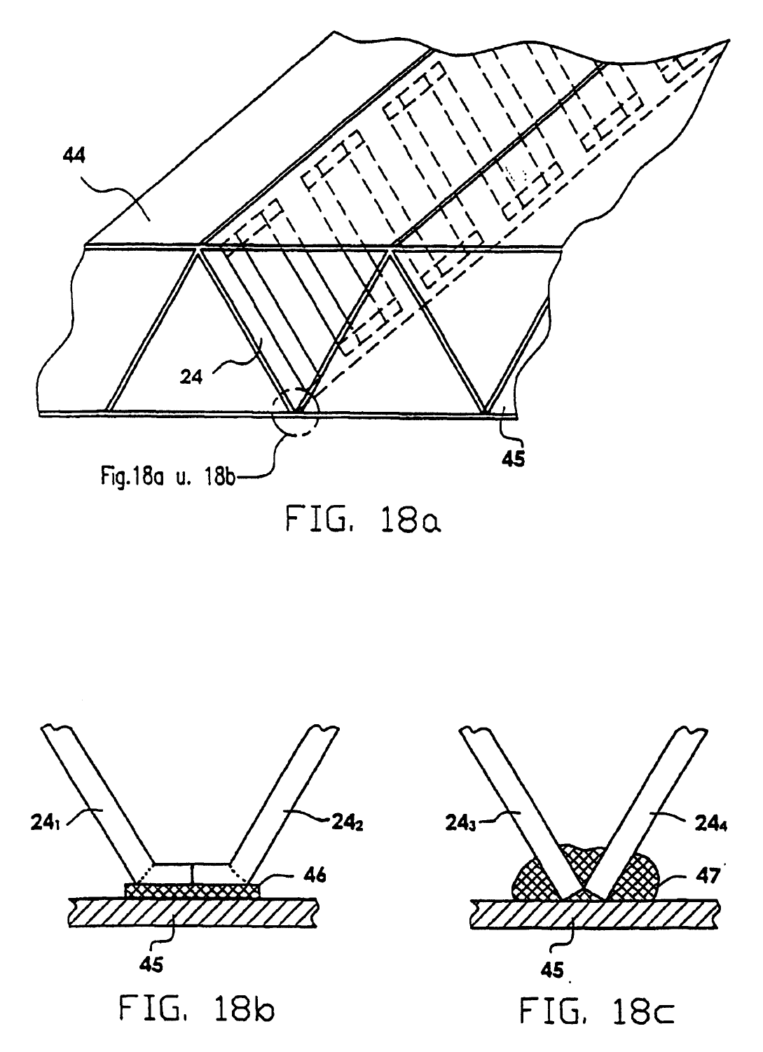

FIG. 17a shows a perspective view of a rolled up strip of substrate with already applied film elements;

FIG. 17b shows a cross-sectional view of an embodiment where a plurality of strips of substrate are interconnected with flexible elements;

FIG. 17c shows a perspective principal view of an already fitted strip of substrate bonded to a curved surface;

FIG. 18a shows a perspective view of a further type of arrangement of the strips of substrate in a “corrugated-paper” form; and

FIGS. 18b,c show details of the arrangement shown in FIG. 18a.

First, a process for the manufacture of thermoelectric pn-junctions is described which combines the inexpensive manufacture of thermoelectric materials for room temperature applications (Bi-SP-Te-Se) with a new transfer technique for the preparation of thin films via conventional crystal growing methods.

Thin V-VI films can only be obtained by means of complicated deposition methods due to their complicated crystal structure. Depending on their subsequent treatment, generators, Peltier coolers or detectors can be made from the produced thermoelectric pn-junctions.

The manufacturing procedure for thermoelectric pn-junctions described herein utilizes the mechanical anisotropies of the V-VI materials. All of the required V-VI materials possess a layer structure. The atoms in one layer (C-plane) are held together by strong bonds. The materials have a good stability within these layers (C-plane). However, the individual layers are held together by weak Van der Waals bonds (Van der Waals materials). Therefore, these materials can be easily split along the layers.

At the same time, the better thermoelectric properties are also present in the C-plane, i.e. in parallel to the layers.

In a preparatory procedure step, the crystal material to be processed is grown as a so-called monocrystal [(Bi₁₋ₓSbₓ)₂(Te_{1-y}Se_{y})₃], wherein 0≦x, y≦1, by adding appropriate dosing substances for p- or n-dosage. Here, the C-plane, in parallel to which the crystal can be easily split, is perpendicular to the growth direction (arrow direction in FIG. 1a) of the crystal. Consequently, the Van der Waals bonds also exist in the cutting plane drawn in FIG. 1a. That is, the Van der Waals bonds keep layers together which are stacked in the arrow direction.

A grown V-VI monocrystal, in which the orientation of the C-plane is known, is then sawn into rods 1 (width b, length l, height hₖ), such that the C-plane is lying in parallel to the front face of the rod (FIG. 1b). Here, the dimensions l (length of the future thermocouple (TE)-leg) and b (preliminary width of the future TE-leg) can be between 50 μm and 10 cm, the height hₖ of the rods 1 can be between 1 mm and 50 cm, this upper limit being only defined by the related crystal growing procedure.

In a following step, for example, the width b of the rod can be subsequently further reduced by a mechanical or chemical removal (width b′), optimally by clamping or gluing such a rod 1 into a mounting 2 after the sawing operation, for example for ensuring a tight tolerance. For doing so, the sawn rods 1 (FIG. 1b) are placed into a mounting 2 with an indentation (FIG. 2) and fixed with an adhesive, for example with wax, photosensitive resist or another adhesive, which can be removed after the thinning. The mounting 2 is now clamped into a polishing machine and thinned down to the desired thickness b′. This can be done purely mechanically or/and with the well-known chemical polishing/etching or other processes. Here, the mounting 2 contemporaneously defines the amount of the material to be removed by the depth of its recess. After the thinning, the TE-rod 1 is released from the mounting. Depending on the fixing adhesive used, this can be done with acetone in case of photosensitive resist or by heating in case of wax. Subsequently, the released TE-rod is cleaned.

In a further preparatory step, diffusion barriers, break-off areas, electrical contacts and insulating materials are then attached to the thus prefabricated TE-rod.

In case of the thickness of the strip to be removed being >100 μm, the following procedure can be used, as is shown in FIGS. 3 to 9. First, a diffusion barrier is applied to the front faces of the TE-rod.

As the current or the temperature gradient, respectively, in the completed thermoelectric element (generator, cooler or detector) is to flow along the side hitherto referred to as lₖ, additional diffusion barriers have to be applied between the TE-rod material and the future electrical contact materials (Cu, Au, Ag, In, Al and Bi, Pb, Sn or alloys thereof). For doing so, the rod 1 is coated with photosensitive resist and exposed such that after the structuring of the photosensitive resist only the bottom, the top wall and the side walls are completely or partly protected by the photosensitive resist as regions 4 of the rod 1, as shown in FIG. 3. Alternatively, a covering by a scotch tape, mechanical shading or the like are possible. Here, by a variation of the length I_{PR} (O<I_{PR}≦lₖ), apart from the front faces 5 in FIG. 3 actually to be provided with a diffusion barrier, a part of the side faces of the rod 1 can be kept free for this purpose.

For cleaning the exposed regions of the rod 1, which will be contaminated by sawing and optional polishing the rods, chemical etching as it is generally known can be used.

Now, a diffusion barrier 7 of Ni, Cr, Al or other materials stated in literature (thickness=10 nm-10 μm) is applied to the cleaned surfaces. The diffusion barrier can be applied either galvanically or with other common deposition processes (cf. e.g. FIG. 4b).

Then, electrical contacts 9 are applied to the diffusion barriers or parts thereof (front faces). This is done using the following steps:

First, the shading 4 shown in FIG. 3 is removed, in case of photosensitive resist possibly with acetone. The rod 1 is now again coated with photosensitive resist 6, 8 and structured (partly illuminated with light), such that only the front faces 5 (FIG. 4a) or the front faces and parts of the diffusion barrier 7 applied to the side faces are not shaded (FIG. 4b). Known materials for the electrical contacts, e. g. Au, Bi, Ni, Ag, Bi/Sn/Pb/Cd-eutectics, are now applied to the still exposed regions of the diffusion barrier 7 with the common deposition processes or with electro-deposition.

Alternatively, the second structuring step described herein (application of another shading) can be omitted and the electrical contacts 9 can be applied directly after the application of the diffusion barrier 7. In both cases, the thickness of the electrical contacts is between 1 μm and 1 cm.

As an alternative, it is also possible not to apply any electrical contacts to the diffusion barriers, if these are already applied to the substrate foil described below or will be applied after the joining of the TE-materials and the substrate foils, e.g. by thermal evaporation.

As a next step, in this suggested first type of process, the sides and/or front faces of the rod 1 are provided with break-off areas which define the thickness d of a future thermoleg (film element). The break-off areas can be provided in a defined manner by scribing or sawing as shown in FIGS. 6a, b.

In doing so, at least the metallization (diffusion barrier 7 and electrical contact metal 9) have to be penetrated in order to be able to later utilize the ease of divisibility of the rod material 1 between two opposing break-off areas. It is alternatively or in combination possible to provide the break-off areas (also) at the long side faces.

Furthermore, the thickness of the saw blade (saw wire, blade) dₛ has to be smaller than half the desired thickness d of the future thermoleg. The lower limit of the thickness of the cut is restricted by dₛ, saw blades for wafer saws, however, are available with a thickness of up to dₛ=15 μm. Therefore, this method of providing break-off areas is suited for a thickness of the thermolegs of >100 μm.

In a case where the thickness of the strip to be removed (completed TE-element) is >2 μm, the following process is suggested, as the provision of the break-off areas for a desired thickness of the thermocouples of <100 μm according to the process suggested first is critical (saw blades are too thick).

In the process described below, many of the steps are similar or equal to those of the process described first. Therefore, only the respective differences or preferred alternatives are described in the following:

In contrast to the previously described process, here the diffusion barrier 7 is first deposited on the whole surface of the TE-rod 1 in a preparatory step, as shown in FIG. 7a. Then, after a first structuring at the front faces, contact material 9 can be applied, as described in the first process. Depending on the strip of substrate, the metallization 9 can be omitted. The whole surface of the coated rod 1 is then covered with photosensitive resist or a corresponding covering and subsequently structured such that cross-stripes of the thickness dₛ are formed where later the break-off areas will be formed.

By means of photolithography, regions of the thickness dₛ are removed from the diffusion barrier at a distance d, the regions which will later form the TE-elements remain covered.

As an alternative to the structuring method described herein, the diffusion barrier 7 can already be applied onto the surface of the rod in a strip-like manner by means of a shadow mask, such that stripes of the thickness dₛ are left open in between.

With known wet-chemical etching processes, now the break-off areas can be defined in the exposed regions. The depth of the break-off areas can be adjusted via the etching duration.

In a further step, now the front faces of the TE-rod are protected with photosensitive resist or the like, and the diffusion barrier is etched away from the center of the rod. Subsequently, the photosensitive resist is removed, corresponding to the rod body represented in FIG. 7b.

In another alternative process, a TE-rod is prepared as follows.

The preparatory steps, including the application of the diffusion barriers, are effected as described in the first process. Then, the TE-rod is fixed to a rotating xy-table with elevation adjustment. With a laser and a corresponding optic, a laser beam is focussed onto one of the front faces 5 of the rod 1, as represented in FIG. 7c. The insulating materials for the protection of the side faces are not shown. Depending on the strip of substrate, the metallization 9 can be omitted here, too.

By shifting the table, in this manner a break-off line can be burnt into this front face. For the next side face, the table is rotated by 90° about the z-axis and moved again into the focus of the laser beam along the x-direction. By means of the shifting speed, the depth of the break-off line can always be defined such that the depth in the TE-rod is always constant (focus on the diffusion barrier: the table becomes slower, focus on the TE-rod: the table becomes faster). As an alternative to this, the depth of the break-off line can also be varied by the variation of the laser intensity at a constant shifting speed.

Naturally, as an alternative to shifting the table, in a similar manner, the laser including the optic can be shifted, or the laser beam can be deflected through an optic such that the break-off lines schematically shown in FIG. 7c are hit.

In the next procedure step, the TE-rod 11 thus prepared and provided with break-off areas is disassembled into individual film elements serving as basis for the TE-elements. The removal of the films along the break-off lines of the TE-rod can again be performed in various ways. In the process, the films are removed along the predefined break-off areas, in each case by utilizing the mechanical properties of the V-VI materials.

In a first alternative to the following procedure step, the TE-rod 11 is laterally fixed in a lift-off device by two plane-parallel clamping jaws 13, 15 represented in FIG. 8a. By means of an elevation adjustment 16, the TE-rod 11 is oriented such that the lower limit of the break-off lines around the rod ends with the surfaces of the clamping jaws 13, 15. In the process, the correct elevation adjustment is determined by a direct observation of the side faces with a microscope. As an alternative, the position of the break-off line can also be determined by optical reflection measurements (difference in reflection, diffusion barrier and/or electrical contact materials with respect to the TE-material exposed at the break-off area).

In the process, the splitting direction is selected such that the splitting line extends in parallel to the long side of the TE-rod 11.

In a variation to the lift-off device shown in FIG. 8a, in the lift-off devices shown in FIGS. 8b and 8c, the respective height is regulated by means of adjusting wheels 13a and 15a or 13b and 15b, respectively, which are mounted in the clamping jaws 13, 15 and engage the break-off areas at both sides and thus perform the positioning of the TE-rod 11, e.g. via a servomotor (stepping motor).

A strip of substrate 24 described more in detail below is inserted and fixed in a receiver 14 of the lift-off device, such as shown e.g. in FIG. 10a and described more in detail later.

As shown in FIG. 8a, the receiver 14 is now pressed onto the surface of the TE-rod 11 in order to provide a firm bond between the surface (upper side face) of the TE-rod 11 and the strip of substrate 24. By pulling the receiver 14 upwards and pressing a blade 12 of the lift-off device into the break-off area t the same time, a film 11a, the thickness d of which is defined by the break-off areas, is lifted off from the remaining TE-rod 11 and transferred to the strip of substrate 24. In the process, a film or film component 11a, respectively, consists of one or several planes of films held together by strong bonds within the plane and by weak bonds between these planes.

Analogously, the lifting off and splitting is always effected in the direction of the short side of the rod (b, b′).

As the TE-rods 11 used herein only have weakly bonded Van der Waals planes in parallel to the surface, a surface which is largely atomically even is formed on the TE-rod 11 after the removal of one film (component 11a) (at the removed film 11a as well as at the upper side of the remaining TE-rod 11). Therefore, the lift-off procedure described herein can be repeated after the shifting of the strip of substrate 24 and a new adjustment of the height of the TE-rod 11, until the inserted TE-rod is used up.

Here, the supply as well as the storage of the not yet fitted strip of substrate 24 preceding the connection of the TE-film with the strip of substrate 24 can be effected in the form of the roll of a camera with feed mechanism, as is schematically represented in FIG. 10b. Here, FIG. 10b is shown rotated by 90° as compared to FIG. 10a.

In the process, the strip of substrate is shifted such that a new adherend for receiving the next material film piece is available. The “fitted” strip 24 is then, for example, wound up like the roll of a camera. Both rolls can comprise spiral guides for the strip of substrate. Another option of the mentioned separation process along the break-off lines represents a blade 12 which is incited to perform mechanical vibrations by means of a (supersonic) transducer.

In the variation shown in FIG. 8b of the lift-off device shown in FIG. 8a, the adjusting wheels 13b and 15b additionally serve as separation devices for splitting off the individual films. Here, the individual films are separated by a rotation in opposite directions (the same sense of rotation) of the adjusting wheels, such that one adjusting wheel 15b presses the bottom rest of the TE-rod downwards while the other adjusting wheel 13b presses the film to be lifted off upwards splitting it off along the break-off area.

Another alternative to the just described procedure, but also for supporting the defined splitting along the break-off lines, is to provide different temperatures at the clamping jaws 13, 15 and the receiver 14 for the strip of substrate 24, as shown in FIG. 9.

Due to the poor thermal conductivity of the V-VI materials, by heating the receiver for the strip of substrate 24 with respect to the clamping jaws 19, 20 maintained at a constant temperature, an extension of the part of the TE-rod (11) not being clamped with respect to the mounted rest of the rod 11 can be attained. For achieving the temperature gradient, here the receiver 17 for the adhesive strip of substrate and the clamping jaw 18 are connected by a thermal insulator (e.g. glass, plastics) 21. In this plane, stresses in the TE-film arise due to the sudden temperature change in the TE-rod 11 at the level of the surfaces of the clamping jaws (19, 20). By tilting the mounting 17 for the strip of substrate, the film will crack along the plane distorted due to the temperature gradient. As the clamped part of the rod 11 is maintained at ambient temperature via the clamping jaws 19, 20 no damage will occur in the clamped area.

Another alternative process for defining the break-off areas is to add lithium (Li) already when growing the crystals or to subsequently implant it at the desired layers. When the crystal is wetted along the crystal, it cracks along these inclusions.

In a further embodiment, the described transfer process also permits the transfer from one stack to another. In this embodiment, by an appropriate deposition of the separated piece of material onto a second support (also crystal rod), even new combinations (p/n/p/n-layer stack) can be realized.

Advantages of the separation device and the transfer process according to the invention are the ideally atomically even separation which can be frequently repeated at a crystal rod or stack of films. By means of the transfer process with the lift-off device described below, a defined deposition of the separated thin stacks of films can be ensured, and from this point on they can be further processed in a defined manner. FIG. 10a shows the assembly of a mounting 14, 17 for strips of substrate 24 as it is employed in a lift-off device shown in FIGS. 8 and 9. Several channels 22 are contained in the mounting 14, 17, which are connected with a suction device (vacuum pump) and/or with a source of compressed air. Via the number and dimensions of the channels 22 connected with the suction device, the shape of the part of the strip of substrate to be fixed can be determined. The strip of substrate 24 is laced up into the one guide rail 23 and positioned such that the part to be fixed is lying under-the suction channels 22. By evacuating the channels 22, the strip of substrate 24 is taken in and fixed. After the strip of substrate 24 has been placed onto the TE-rod 11, the compressed air line can establish a firm connection between the adhesive surface and the TE-rod 11.

As strips of substrate 24, plastic foils gluey on one side (d=5 μm to 1 mm) are preferred. In a first embodiment, these strips of substrate 24 are prepared such that they already contain electric connection elements.

One embodiment of such a strip of substrate according to the first embodiment is depicted in FIGS. 11a and 11b (Version A).

An oblong plastic foil 24a which is a poor conductor of heat and has a predetermined width and thickness is provided with an adhesive film 25 at those spots where later the TE-films 29 removed from the TE-rod 11 are to be positioned. For electrically contacting the lifted off films 29, on both front faces of the adherends 25, low melting point solders 26 having a preferred thickness between 1 μm and 100 μm are already applied. The distance of the solders 26 from the adherends 25 is to be dimensioned such that, when the substrate foil is folded along bending areas 28 formed in the longitudinal direction of the foil, the solders 26 meet the side faces 5 of the TE-films 29 protected by diffusion barriers 7.

Another embodiment of a strip of substrate according to a second version (B) is shown in FIG. 12.

In contrast to version A, here any previous structuring of the adherends 25 as well as the previous formation of electrical contacts 26, 27 is dispensed with. At the edge of the strip of substrate 24b, there is a non-adhesive area which makes possible a shifting into the mounting 14, 17 for the strip of substrate 24b.

When this strip of substrate 24b is used, the electrical contacting is effected after the TE-films 29 have been fixed onto the substrate foil 24b.

A third embodiment in the form of the strip of substrate 24c (version C) is shown in FIG. 13.

It is formed and processed like the strip of substrate 24b, however, adherends 25 are only formed at those spots where later the TE-films 29 are to be applied (see FIG. 13a).

An alternative embodiment which can be combined with all previously described strips of substrate 24a, 24b, 24c, is the strip of substrate 24d of version D shown in FIG. 13b. Here, the adherends 25 can be designed as in versions A, B or C. However, the substrate foils 24d are made of two or several layers. A thick layer 24e serves for stabilizing the actual strip of substrate 24f during the manufacture. A thin layer 24f is on layer 24e on which the adherends 25 for lifting off the films are situated. These layers 24e, 24f differ in their composition such that they can be chemically solved in a selective manner. Thus, the complete production process can be performed on one mechanically stable foil 24d and only the stabilizing portion 24e can be removed for the future application.

In the following, the completion of the thermoelectric element as a thermal generator, detector, cooler, using several TE-films obtained according to the above described procedure steps and the respective different substrate foils are described.

In general, generators, coolers and detectors differ in their geometrical dimensions, the number of elements used and the use of various substrate materials. Therefore, with only one process, all three types of devices can be manufactured, so that it suffices to describe the manufacture of one pn-junction in place of a complete thermoelectric element.

First, the manufacture of a TE-element with the substrate foil 24 of version A will be described.

The required number of p- and n-films is applied to the substrate foil 14a in the alternating sequence indicated in FIG. 11. The thus fitted substrate foil shown in FIG. 14a in cross-section is placed into an adequate mounting 31. The substrate foil 24a is centered with a centering aid 32 on the mounting 31. Flaps of plates 33 movably arranged at the mounting 31 fold the substrate foil at the bending spots 28, thereby pressing the electrical contacts on the foil 26 against the diffusion barriers 7 of the lifted off TE-films 30.

By heating the plates 33 with the heating 34 above the melting point of the low melting point solder 26, the individual p- and n-films, respectively, are interconnected to form thermocouples. The projecting parts of the foil 26 are then cut off.

Finally, the two outer electrical contacts are provided with cables 37 for power feed (cooler) or withdrawal (generator, detector). Such a thermoelectric element with a thermocouple pn is shown in FIG. 14c. Of course, several pairs can also be combined in series or in parallel in a finished TE-element.

In the following, the manufacture of a thermoelectric element with substrate foils 24b, c of version B or C is illustrated more in detail.

As with the strips of substrate 24a of version A, the p- and n-films 35, 36 of the TE-rod 11 are lifted off onto the substrate foil 24b, c in the desired alternating sequence. Then, a thin double sided adhesive, preferably transparent foil 38 with release foil 39, as they are shown in FIGS. 15b, c, d, is bonded to the fitted substrate foil (FIG. 15a). The release foil 39 (in the following also referred to as shadow mask) comprises recesses, as does the bonding sheet 38 (cf. FIGS. 15b, c, d), which alternately interconnect two adjacent front faces of the TE-films in the longitudinal direction of the foils in the form of a gap opening to the top. By bonding them in a sandwich manner, the positions for the electric lines between the films 35, 36 on the substrate foil 24, b, c, can thus be easily defined.

Now, first the diffusion barrier and the electrical contact materials are applied to the thus prepared substrate foil (thermal evaporation, sputtering), if this has not already been done according to the process described in the beginning. By drawing the release foil 39 off the double sided bonding sheet 38, only the desired electric connections of the p- and n-materials now remain on the substrate foil. In order to avoid shadow effects or under-steam when depositing the electrical contacts, in the double sided bonding sheet 38, indentations are provided at the positions of the p- and n-films 35, 36 (FIG. 15c). Thereby, the double sided bonding sheet 38 lies even on the substrate foil. This is shown in FIG. 15d.

Optionally, the double sided bonding sheet 38 can be finally drawn off or a new release foil without recesses can be bonded to its upper side.

If the foil is drawn off, however, the height of the recess has to be larger than d, i.e. the foil may only lie against the films, but not adhere to them.

Alternatively, similar to the mechanical stabilization 24e shown in FIG. 13, the material can be selected such that the bonding sheet 38 is chemically removed (dissolved) from the substrate foil 24 in a selective manner.

Alternatively, with the substrate foils 24b, c of version B or C, the following procedure step for completing the thermoelectric elements is also possible.

As described above and represented in FIG. 15a, two strips of substrate 24g, h are fitted with TE-films 35, 36. Now, the electrical contacts are applied to both strips of substrate 24g, h with a modified version 38a of the shadow mask 38, as is shown in FIG. 16a. Here, on the first substrate foil 24g, the lower metallizations 42 have to extend from an n-leg 35 to a p-leg 36. On the second substrate foil 24h, however, these metallizations (consisting of diffusion barrier and solder material) are offset by one leg, i.e. they extend from the left to the right, seen from a p-leg 36 to an n-leg 35.

Now, the one electrically insulating foil 41 shown in FIG. 16b is bonded to one of the strips of substrate.

As an alternative, the upper contact points are shadowed with a mask inverse to the foil 41 (e.g. photosensitive resist). Then, an electrically insulating film is applied, for example by means of a spraying method, before the shadings are removed again. In this alternative process, the use of films with a thinner embossment reduces parasitive heat flows.

Subsequently, the two strips of substrate 24g, h, are superimposed by bonding such that always a p- and an n-film 35, 36 are lying one upon the other. By heating the contact points from the outside, now the electrical contacts are formed between the p- and n-films 35, 36, as shown in FIG. 16d.

With any of the above-described embodiments of the present invention, the flexibility of the employment of the thermoelectric elements is essentially increased. The structures realized on the strip of substrate can be flexibly transferred to the respective place of application with the process according to the invention (for example in a thermal generator: bonding between hot and cold water conduit). Furthermore, the adhesive tape can be completely or partially removed after the transfer, which makes the thermoelectric element according to the invention even smaller and more flexible.

By the use of bendable base materials, according to the invention one obtains thermoelectric elements which are likewise flexible.

The thin films can be protected by a mechanical reinforcement of the adhesive tapes at the points where later the films are drawn off. The whole strip of substrate, however, remains flexible and can therefore be e.g. rolled up, as shown e.g. in FIG. 17a. This leads to a higher packing density and thus to an optimal utilization of e.g. waste heat.

By means of flexible connections 43 between the substrate carriers 24, the flexibility of the elements can be even enlarged by one dimension, as shown in FIG. 17b. By this combination, one obtains large-surface elements which adapt to convex surfaces (for example a thermal generator in a car's roof for additional energy in a passenger car, cf. FIG. 17c).

Another possibility of combining the already fitted strips of substrate 24 for future applications is represented in FIGS. 18a-c. In FIG. 18a, an arrangement in a “corrugated-paper” form is shown.

In a first method (FIG. 18b), the strips of substrate 24 of an arbitrary one of the above-described embodiments is fixed between two backings 44, 45 or base plates, e.g. by gluing. This is done at the projecting areas of the strips of substrate 24₁, 24₂, via adhesive areas 46 of the backings 44, 45.

Alternatively, as shown in FIG. 18c, the substrate foils 24₃, 24₄ can also be bonded with an electrically insulating adhesive 47 of good heat conduction. If the adhesive 47 contacts the thermocouples at the warm or the cold side, respectively, these are thermically well coupled to the source of heat or heat sink, respectively.

As the thermocouples according to the invention as standard materials are within the room temperature region of Van der Waals materials, the process according to the invention offers the possibility of realizing the applications common in thermoelectric engineering (generators, Peltier coolers, sensors, etc.) on adhesive tapes.

By constructing complete thermoelectric elements, for example thermal generators in roll form, the same can be, for example, well integrated into cylindrical bodies (tubes). Due to the “corrugated-paper” design, a mechanically stable arrangement with a low thermal output at the same time is enabled which permits the integration at convex and large surfaces.

Here, individual strips of substrate, on which thermocouples are arranged in a meander-like manner, are themselves arranged in a meander-like manner between two backing elements, in particular foils. This results in a zigzag structure.

The process according to the invention makes it possible to realize the applications common in thermoelectric engineering. This permits an inexpensive integration into a plurality of products. However, the described processes and devices can be used for other Van der Waals materials, as well, as they are employed, for example, in photovoltaic engineering.

1. Thermoelectric element, characterized in that it contains at least two electrically coupled semiconductor components (30, 35, 36) or one semiconductor component (35) and a metal film (36) on at least one insulating substrate (24, 24a, b, c, d), the substrate (24, 24a, b, c, d) being a flexible foil element.

2. Thermoelectric element according to claim 1, characterized in that at least one of the semiconductor components (36) comprises a p-doping and at least one of the semiconductor components (35) comprises an n-doping.

3. Thermoelectric element according to one of claims 1 or 2, characterized in that at least one of the semiconductor components (30, 35, 36) comprises a polycrystalline structure with a definite orientation of preference of the crystals (texturing).

4. Thermoelectric element according to one of claims 1 to 3, characterized in that at least one of the semiconductor components (30, 35, 36) comprises a monocrystalline structure.

5. Thermoelectric element according to one of claims 1 to 4, characterized in that at least one semiconductor component is made of a film-like material having strong bonds within the film planes, and the crystal planes of which are held together by weak bonds.

6. Thermoelectric element according to claim 5, characterized in that the individual film planes are held together by Van der Waals forces.

7. Thermoelectric element according to one of claims 1 to 4, characterized in that at least one semiconductor component (30, 35, 36) has been deposited onto a crystalline substrate by means of film deposition methods, such as in particular MOCVD, MBE, PVD, sputter methods.

8. Thermoelectric element according to one of claims 1 to 5, characterized in that at least one semiconductor component is made of a film-like material between the films of which lithium is embedded.

9. Thermoelectric element according to one of claims 1 to 8, characterized in that the semiconductor components (30, 35, 36) are fixed to said at least one substrate (24, 24a, b, c, d) by means of gluing.

10. Thermoelectric element according to one of claims 1 to 9, characterized in that the substrate (24d, 24h, 24g) has a multi-layer design.

11. Thermoelectric element according to one of claims 1 to 10, characterized in that the substrate (24a, 24g, 24h) comprises flexible strip conductors (26).

12. Thermoelectric element according to one of claims 1 to 11, characterized in that the semiconductor components (35, 36) comprise diffusion barriers at their points of contact.

13. Thermoelectric element according to one of claims 1 to 12, characterized in that several films of substrates (24g, h) and/or semiconductor components (35, 36) are arranged one upon the other.

14. Thermoelectric element according to one of claims 1 to 13, characterized in that several films of fitted strips of substrate (24) are arranged one upon the other in the form of a roll, in particular by rolling them up.

15. Thermoelectric element according to one of claims 1 to 13, characterized in that one or several films of fitted strips of substrate (24) are arranged between backings (44, 45) in a meander-like manner.

16. Process for separating and transferring in particular crystalline layer materials, wherein the layer materials comprise individual parallel film planes containing strong bonds and wherein the individual film planes are coupled to adjacent film planes by weak bonds, characterized in that a film component (11a) comprising one or several coupled film planes is fixed to a substrate (24) before these film components (11a) are separated from an adjacent film plane.

17. Process for separating and transferring layer materials according to claim 16, characterized in that the layer material comprises adjacent film planes held together by Van der Waals bonds.

18. Process for separating and transferring layer materials according to claim 16 or 17, characterized in that a rod body (1, 11) is made of the layer material, in which rod body a number of film components (11a) is arranged one upon the other in the direction of the weak bonds.

19. Process for separating and transferring layer materials according to one of claims 16 to 18, characterized in that the individual film components (11a) are separated by means of a blade by splitting them off.

20. Process for separating and transferring layer materials according to one of claims 16 to 19, characterized in that the separation is effected by means of tilting and/or by utilizing temperature differences between adjacent film components (11a).

21. Process for separating or transferring layer materials according to one of claims 16 to 20, characterized in that the rod body (1, 11) is provided with break-off areas (10) before the separation.

22. Process for separating and transferring layer materials according to claim 21, characterized in that the break-off areas (10) are formed by means of an etching process.

23. Process for separating and transferring layer materials according to claim 21, characterized in that the break-off areas (10) are formed by means of a laser.

24. Process for separating and transferring layer materials according to claim 21, characterized in that the break-off areas are already introduced during the production of crystals of the layer material by a purposeful embedding of weak points (impurity atoms), in particular by epitaxy processes.

25. Process for separating and transferring layer materials according to one of claims 16 to 24, characterized in that the separated film components (11a) are fixed to defined spots of the substrate (24) and are intermediately stored for further use.

26. Process for separating and transferring layer materials according to one of claims 16 to 25, characterized in that the fixing is effected by means of an adhesive film (25) applied to the substrate (24).

27. Process for separating and transferring layer materials according to one of claims 16 to 26, characterized in that the intermediate storage of the substrates (24) is effected before or after the application of the film components (11a) in a roll form.

28. Process for the manufacture of a thermoelectric element, characterized in that at least two semiconductor components (35, 36) or one semiconductor component (35) and a metal or a metalloid film (36) are fixed to at least one insulating substrate (24) and interconnected in an electroconductive manner.

29. Process for the manufacture of a thermoelectric element according to claim 28, characterized in that the semiconductor components (35, 36) and/or the metal film (36) are film components (11a) which have been separated from a layer material according to a process according to claims 16 to 27.

30. Process for the manufacture of a thermoelectric element according to one of claims 28 or 29, characterized in that strip conductors (26) are applied on the substrate (24, 24a) before the semiconductor components (35, 36) are fixed to the substrate (24, 24a).

31. Process for the manufacture of a thermoelectric element according to one of claims 28 to 30, characterized in that the semiconductor components (35, 36) are interconnected in an electroconductive manner after they have been fixed to said at least one substrate (24, 24a-h).

32. Process for the manufacture of a thermoelectric element according to one of claims 24 to 31, characterized in that the rod body (1, 11) is provided with diffusion barriers (7) at its outer sides (5) vertically with respect to the direction of the weak bonds.

33. Process for the manufacture of a thermoelectric element according to one of claims 28 to 32, characterized in that the thermoelectric element is realized by rolling up one or several flexible backings (44, 45).

34. Process for the manufacture of a thermoelectric element according to claim 33, characterized in that the front faces of the roll serve as hot and warm sides, respectively, and wherein these front faces can additionally serve as electrical contacts of the element.

35. Process for the manufacture of a thermoelectric element according to one of claims 28 to 32, characterized in that one or several flexible substrates are connected with further foil substrates for a mechanical stabilisation and an electrical contact.

36. Process for the manufacture of a thermoelectric element according to one of claims 28 to 35, characterized in that several substrates, on each of which a number of semiconductor components has been arranged, are arranged between backings in a meander-like manner.

37. Device for separating and transferring layer materials, the layer materials comprising individual parallel film planes containing strong bonds, and wherein the individual film planes are coupled to adjacent film planes by weak bonds, characterized in that the device comprises: clamping means (13, 15) for a layer material,
receiving means (14) for a film component (11a) separated from the layer material, and
separation means (12, 13b, 15b, 17).

38. Device for separating and transferring layer materials according to claim 37, characterized in that furthermore a positioning device (16, 13a, 15a) for exactly positioning the layer material is provided.

39. Device for separating and transferring layer materials according to claim 37 or 38, characterized in that the receiving means (14, 17) comprises a mounting for a substrate (24) by which the substrate can be positioned relatively to the film component (11a) to be separated.

40. Device for separating and transferring layer materials according to one of claims 37 to 39, characterized in that the receiving means (14, 17) comprises a pressing device by which the substrate (24) can be pressed at one surface of the film component (11a) and connected thereto.

41. Device for separating and transferring layer materials according to claim 40, characterized in that the pressing device comprises a vacuum pump or a press pump.

42. Device for separating and transferring layer materials according to one of claims 37 to 41, characterized in that the device comprises a storage means in which the substrate is stored before and after the reception of a film component (11a).
